(19) United States
(12) Patent Application Publication
(10) Pub. No.: US 2024/0224723 A1
(43) Pub. Date: Jul. 4, 2024

(54) LIGHT EMITTING DISPLAY DEVICE AND METHOD OF MANUFACTURING THE SAME

(71) Applicant: LG DISPLAY CO., LTD., SEOUL (KR)

(72) Inventors: Su Min AN, Gyeonggi-do (KR); Ji Sub PARK, Gyeonggi-do (KR); Young Chul SHIN, Gyeonggi-do (KR); Young Cheol CHAE, Gyeonggi-do (KR); Byeong Gon KIM, Gyeonggi-do (KR)

(73) Assignee: LG DISPLAY CO., LTD., SEOUL (KR)

(21) Appl. No.: 18/379,027

(22) Filed: Oct. 11, 2023

(30) Foreign Application Priority Data
Dec. 30, 2022 (KR) 10-2022-0190677

(51) Int. Cl. H10K 59/80; C09D 1/00; C09D 5/16; H10K 59/40

(52) U.S. Cl. CPC H10K 59/873; C09D 1/00; C09D 5/1662; H10K 59/40

(57) ABSTRACT

Disclosed is a light emitting display device configured to prevent a liquid encapsulation material from overflowing a dam and a method of manufacturing the same. The light emitting display device includes a nanostructure configured to surround an active area and provided on a first inorganic encapsulation layer over at least one dam pattern, and an organic encapsulation layer provided on the first inorganic encapsulation layer in an area inward from the nanostructure.

### CROSS-REFERENCE TO RELATED APPLICATIONS

This application claims the benefit of Korean Patent Application No. 10-2022-0190677, filed on Dec. 30, 2022, which is hereby incorporated by reference as if fully set forth herein.

### BACKGROUND

### Field of the Disclosure

The present disclosure relates to a display device, and more particularly to a light emitting display device configured to prevent a liquid encapsulation material from overflowing a dam and a method of manufacturing the same.

### Background

With development of information society, demand for display devices for displaying images in various forms is increasing.

A light emitting display device in which light emitting devices constitute pixels does not require a separate light source unit, and is thus favorable in view of slimness or flexibility and has an advantage of good color purity.

For example, a light emitting device includes two different electrodes and an emission layer therebetween, and when electrons generated from one electrode and holes generated from the remaining electrode are injected into the emission layer, the injected electrons and holes are combined to form excitons, and light emission occurs while the excitons thus formed fall from an excited state to a ground state.

Since a light emitting display device displays an image by light emitted from the emission layer, it is necessary to protect light emitting devices to prevent deterioration of the light emitting devices due to external factors. To this end, the light emitting display device includes an encapsulation structure.

### SUMMARY

To encapsulate light emitting devices, there is illustrated a thin film barrier in which inorganic and organic encapsulation layers are alternately formed. The organic encapsulation layer of the thin film barrier is formed by applying a liquid organic encapsulation material to a thickness sufficient to cover particles generated during processes.

However, it is difficult to control spreading of the liquid material after application onto a flat surface. Hence, the light emitting display device may be configured such that the margin of the outer area is increased or a dam pattern having a predetermined thickness is further provided in the outer area in consideration of spreadability of the organic encapsulation material.

However, even when the dam pattern is provided, in the case in which the width or height of the dam pattern is not sufficient, a material for forming an organic encapsulation layer may spread beyond the dam pattern, and in the case in which the number of dam patterns is increased, all of the area occupied by the dam patterns and the area required to maintain the space between the dam patterns are regarded as ineffective, and the ineffective area that is not used for actual display may increase, which is undesirable.

Accordingly, the present disclosure is directed to a light emitting display device and a method of manufacturing the same that substantially obviate one or more problems due to limitations and disadvantages of the related art.

The present disclosure provides a light emitting display device and a method of manufacturing the same, in which a barrier pattern configured to prevent a material for forming an organic encapsulation layer from spreading is formed on a dam, thereby preventing outside air and water from entering the inside of the light emitting display device from the lateral side, ultimately protecting light emitting devices.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a light emitting display device is capable of preventing introduction of outside air and water from the lateral side by forming a barrier pattern configured to prevent a material for forming an organic encapsulation layer from spreading.

A light emitting display device according to an aspect of the present disclosure may include a hydrophilic material layer on a first inorganic encapsulation layer over at least one dam pattern.

A light emitting display device according to another aspect of the present disclosure may include a nanostructure on a first inorganic encapsulation layer over at least one dam pattern.

A method of manufacturing a light emitting display device according to an aspect of the present disclosure includes preparing a substrate having an active area including a plurality of sub-pixels and a non-active area surrounding the active area, forming a light emitting device in each of the plurality of sub-pixels, forming at least one dam pattern in the non-active area to surround the active area, forming a first inorganic encapsulation layer covering the light emitting device in the active area and the non-active area including at least one dam pattern, forming a nanostructure surrounding the active area on the first inorganic encapsulation layer over at least one dam pattern, forming an organic encapsulation layer on the first inorganic encapsulation layer in an area inward from the nanostructure, and forming a second inorganic encapsulation layer covering the organic encapsulation layer and the nanostructure on the first inorganic encapsulation layer and the nanostructure to extend outward from the nanostructure.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate aspect (s) of the disclosure and together with the description serve to explain the principle of the disclosure. In the drawings:

FIG. 1 is a plan view showing a light emitting display device according to a first aspect of the present disclosure:

FIG. 2 is a cross-sectional view showing the light emitting display device taken along line I-I′ of FIG. 1 according to the first aspect of the present disclosure:

FIGS. 3A to 3D are cross-sectional views showing a process of manufacturing the light emitting display device according to the first aspect of the present disclosure:

FIG. 4 is a plan view showing a light emitting display device according to a second aspect of the present disclosure:

FIG. 5 is a cross-sectional view showing the light emitting display device taken along line I-I′ of FIG. 4 according to the second aspect of the present disclosure:

FIGS. 6A to 6E are cross-sectional views showing a process of manufacturing the light emitting display device according to the second aspect of the present disclosure; and

FIG. 7 is a cross-sectional view showing a light emitting display device taken along line I-I′ of FIG. 4 according to a third aspect of the present disclosure.

### DETAILED DESCRIPTION

Hereinafter, a description will be given of preferred embodiments of the present specification with reference to the accompanying drawings. The same reference numerals will be used throughout the description to refer to the same or like components. In the following description, if it is determined that a detailed description of the technology or configuration related to the present specification may unnecessarily obscure the gist of the present specification, the detailed description thereof will be omitted. Also, the component names used in the following description are selected in consideration of the ease of writing the specification, and may be different from the part names of the actual product.

The shape, size, ratio, angle, number, etc. disclosed in the drawings for explaining various embodiments of the present specification are exemplary, and the present specification is not limited to the drawings. The same reference numerals designate the same components throughout the specification. Also, in describing the present specification, if it is determined that a detailed description of the related known technology may unnecessarily obscure the gist of the present specification, the detailed description thereof will be omitted. When “include”, “have, “comprise”, etc. mentioned herein are used, other parts may be added unless “only” is used. As used herein, the singular forms are intended to include the plural forms as well, unless the context clearly indicates otherwise.

In interpreting the components included in various embodiments of the present specification, even if there is no separate explicit description, it is understood as including error ranges.

In various embodiments of the present specification, when describing a positional relationship, for example, when the positional relationship of two parts such as “on”, “onto”, “under, “next to”, etc. is described, one or more other parts may be disposed between two parts unless “immediately” or “directly” is used.

In various embodiments of the present specification, when describing a temporal relationship, for example, the temporal order relationship such as “after”, “subsequent to”, “then”, “before”, etc., is described, non-continuous cases may be included unless “immediately” or “directly” is used.

In various embodiments of the present specification, terms such as “first”, “second”, etc. may be used to describe various components, but these terms are only used to distinguish between the same or like components. Accordingly, the component qualified as “first” in this specification may be the same as the component qualified as “second” within the technical spirit of the present specification, unless otherwise noted.

Individual features in various embodiments of the present specification may be partially or entirely coupled or combined with each other, a variety of technical associations and operations are possible, and each of the various embodiments may be implemented independently of each other or together in an associated relationship.

### First Aspect

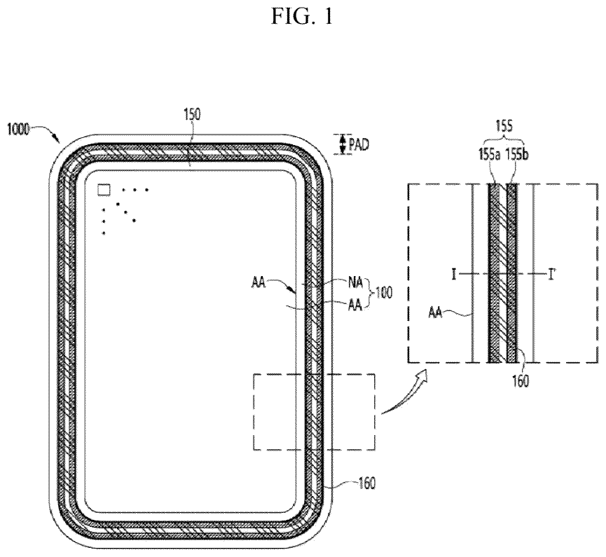

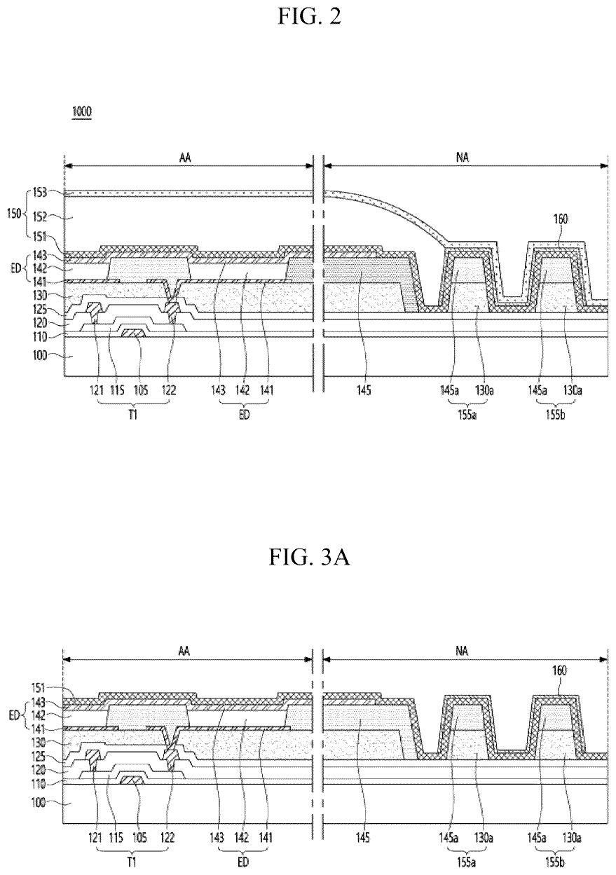

FIG. 1 is a plan view showing a light emitting display device according to a first aspect of the present disclosure. FIG. 2 is a cross-sectional view showing the light emitting display device taken along line I-I′ of FIG. 1 according to the first aspect of the present disclosure.

As shown in FIG. 1, the light emitting display device 1000 according to the first aspect of the present disclosure includes a substrate 100 having an active area AA including a plurality of sub-pixels SP and a non-active area NA surrounding the outer perimeter of the active area AA.

The substrate 100 includes an encapsulation structure 150 (FIG. 2) that protects a light emitting device ED (FIG. 2) provided to each of the sub-pixels SP in at least the active area AA. The encapsulation structure 150 may be provided in the entire active area AA and at least a part of the non-active area NA outside the active area AA.

As shown in FIG. 1, the light emitting display device 1000 according to the first aspect of the present disclosure includes at least one dam pattern 155a, 155b in the non-active area NA of the encapsulation structure 150.

Also, as shown in FIG. 1, the light emitting display device 1000 according to the first aspect of the present disclosure includes a hydrophilic material layer 160 over at least one dam pattern 155a, 155b.

In the encapsulation structure that protects and encapsulates the active area AA, an organic encapsulation layer 152 (FIG. 2) is formed by applying a liquid material, and may have spreadability when applied due to liquid properties. The hydrophilic material layer 160 of the present disclosure functions to prevent the hydrophobic organic encapsulation layer 152 made of a liquid material from spreading onto at least one dam pattern 155a, 155b.

A plurality of gate lines and a plurality of data lines crossing each other may be provided in the active area AA of the substrate 100, and sub-pixels SP may be disposed in each area where the plurality of gate lines and the plurality of data lines cross each other. The configuration of the sub-pixels SP may be variously changed depending on the type of light emitting display device.

For example, the sub-pixels SP may be formed in a top emission manner, a bottom emission manner, or a dual emission manner, depending on the configuration thereof. The sub-pixels SP are units capable of emitting light of their own colors with or without a specific type of color filter. For example, the sub-pixels SP may include red, green, and blue sub-pixels. Alternatively, the sub-pixels SP may include, for example, red, blue, white, and green sub-pixels. The sub-pixels SP may have one or more different emission areas depending on light emitting characteristics. For example, sub-pixels emitting blue and other colors may have different emission areas.

One or more sub-pixels SP may constitute one unit pixel. For example, one unit pixel may include red, green, and blue sub-pixels, and the red, green, and blue sub-pixels may be repeatedly arranged. Alternatively, one unit pixel may include red, green, blue, and white sub-pixels, and the red, green, blue, and white sub-pixels may be repeatedly arranged, or the red, green, blue, and white sub-pixels may be arranged in a quad form.

In some embodiments, the sub-pixels SP may include sub-pixels emitting at least two selected from among red light, green light, blue light, yellow light, magenta light, and cyan light. Also, the plurality of sub-pixels SP may emit their own colors with or without a specific type of color filter. However, the present disclosure is not necessarily limited thereto, and the color type, arrangement type, and arrangement order of the sub-pixels SP may vary depending on the light emitting characteristics, device lifespan, and device specifications.

In an aspect according to the present specification, the color type, arrangement type, arrangement order, etc. of the sub-pixels may be configured in various forms depending on the light emitting characteristics, device lifespan, device specifications, and the like, but the present disclosure is not limited thereto.

At least one side of the non-active area NA of the substrate 100 may include a pad portion PAD including a pad electrode. The pad electrode may be connected to the gate lines and the data lines of the active area AA through a link line. The link line may overlap the hydrophilic material layer 160 and at least one dam pattern 155a. 155b surrounding the non-active area NA.

The encapsulation structure 150) may not be formed in the pad portion PAD. However, the present disclosure is not limited thereto, and when the encapsulation structure 150 is multilayered, some layers thereof may be formed in at least a part of the pad portion PAD.

Meanwhile, as shown in FIG. 1, the hydrophilic material layer 160 and at least one dam pattern 155a, 155b may be formed in a closed loop shape in the non-active area NA. However, the hydrophilic material layer 160 and at least one dam pattern 155a. 155b of the present disclosure are not necessarily a closed loop. In some cases, the hydrophilic material layer 160 and at least one dam pattern 155a. 155b may have an opening in at least a part of the substrate 100.

The hydrophilic material layer 160 may have the same width in the non-active area NA along each side of the substrate 100. However, the present disclosure is not limited thereto, and the width of the hydrophilic material layer 160 may vary depending on the side of the substrate 100. The width of the hydrophilic material layer 160 may be increased on any side of the substrate 100 where the liquid material is excessive among sides of the substrate 100. For example, when the substrate 100 has the pad portion PAD at one side thereof as shown in FIG. 1, the non-active area NA corresponding to the side having the pad portion PAD requires a link line for connection between the pad electrode and lines such as the gate lines, the data lines, etc. in the active area AA. In addition, when the light emitting display device includes a gate-in-panel (GIP) circuit having a gate driver configured to drive gate lines by embedding the gate driver in the substrate 100, one side or both sides of the substrate adjacent to the gate lines may include the gate driver through the same process as a process of forming a thin film transistor of the active area AA. In addition, the non-active area NA of the substrate 100 may include a ground line. As described above, the non-active area NA of the substrate 100 may have a density difference on each side due to different lines and circuit types required for the pad portion and the gate driver, and accordingly, a surface step may be generated and thus spreadability of the liquid material may vary. In the light emitting display device of the present disclosure, the width of the hydrophilic material layer 160 is set to be different at a side having high step density and a side having low step density, whereby spreading of the organic encapsulation layer may be thoroughly prevented regardless of areas even when the liquid material spreads.

In the active area AA, an image may be displayed by light emitted from each sub-pixel SP.

The pad portion PAD of the non-active area NA may be connected to an external printed circuit film or the like to receive an electrical signal from the outside.

Below is a specific description of a light emitting display device according to an aspect of the present disclosure with reference to a cross-sectional view.

As shown in FIG. 2, the light emitting display device 1000 according to the first aspect of the present disclosure includes a substrate 100 having an active area AA including a plurality of sub-pixels and a non-active area NA surrounding the active area, a light emitting device ED provided to each of the plurality of sub-pixels SP in the active area AA (FIG. 1), and an encapsulation structure 150 covering the light emitting device ED.

The encapsulation structure 150 of the light emitting display device 1000 according to the first aspect of the present disclosure includes at least one dam pattern 155a, 155b provided in the non-active area NA, a first inorganic encapsulation layer 151 provided in the active area AA and the non-active area NA, a hydrophilic material layer 160 configured to surround the active area AA in the non-active area NA and provided on the first inorganic encapsulation layer 151 over at least one dam pattern 155a, 155b, a hydrophobic organic encapsulation layer 152 provided on the first inorganic encapsulation layer 151 in an area inward from the hydrophilic material layer 160 and at least one dam pattern 155a, 155b, and a second inorganic encapsulation layer 153 configured to cover the hydrophilic material layer 160 and provided to extend outward from the hydrophilic material layer 160.

The first inorganic encapsulation layer 151 and the second inorganic encapsulation layer 153 of the encapsulation structure 150 functionally prevent penetration of water or outside air introduced in a direction perpendicular thereto, and are formed thinly at a thickness of about 1 μm to 2 μm. The first and second inorganic encapsulation layers 151, 153 may be formed in a gaseous state by vacuum deposition. Moreover, the first and second inorganic encapsulation layers 151, 153 are formed throughout the entire substrate 100 except for the pad portion PAD.

The organic encapsulation layer 152 is formed to a high thickness sufficient to cover particles, etc. generated during processes. Since the organic encapsulation layer 152 may be more vulnerable to outside air and water than the first and second inorganic encapsulation layers 151, 153 due to material properties, it may be positioned inward relative to the first and second inorganic encapsulation layers 151, 153.

Since the hydrophobic organic encapsulation layer 152 needs to be formed thick enough to cover particles and large enough to cover at least the active area AA, it may be formed through spin coating using a liquid hydrophobic organic material. However, the liquid hydrophobic organic material may spread beyond a preset design area after coating (application).

In the light emitting display device of the present disclosure, the hydrophilic material layer 160 is formed on the first inorganic encapsulation layer 151 over at least one dam pattern 155a, 155b, and thus the liquid hydrophobic organic material is prevented from spreading onto at least one dam pattern 155a, 155b due to a difference in wettability between the hydrophilic material layer 160 and the hydrophobic organic material.

As a structure that prevents overflow of a liquid material encapsulation layer known to date, at least one dam pattern is provided in the form of a planarization film that protects a thin film transistor array or a bank that defines the emission portion of each sub-pixel. However, such a dam pattern structure has difficulty completely preventing overflow of the liquid material encapsulation layer, and accordingly, a plurality of dams is spaced apart from each other horizontally. Here, the area occupied by the plurality of dam structures and the space between the dams cannot be used for display, which causes an increase in the non-active area. Moreover, a multilayered dam may be formed by increasing the width of the planarization film dam pattern at the lower position to align the planarization film and the bank formed in different layers, increasing the area occupied by the dam pattern, which is undesirable.

In the light emitting display device 1000 of the present disclosure, the hydrophilic material layer 160 may be formed on the first inorganic encapsulation layer 151 over at least one dam pattern 155a. 155b, so that the liquid hydrophobic organic material may be prevented from spreading onto at least one dam pattern 155a, 155b, thereby solving problems with the structure having the dam pattern such as the area occupied by the dam pattern and expansion of the non-active area.

The hydrophilic material layer 160 of the present disclosure may include a material having an —OH ligand, —COOH ligand, or —POOH ligand and having a glass transition temperature (Tg) of 120° C. or less.

At least one dam pattern 155a, 155b may be configured such that the same material 130a as a planarization film 130 and the same material 145a as a bank 145 are stacked. However, the present disclosure is not limited thereto, and at least one dam pattern may be formed of a material for either the planarization film 130 or the bank 145, or may be formed of a material different from that for the planarization film 130 or the bank 145.

The organic encapsulation layer 152 may be formed of, for example, acrylic resin, methacrylic resin, polyisoprene, vinyl resin, epoxy resin, urethane resin, cellulose resin, or perylene resin.

Each of the first and second inorganic encapsulation layers 151, 153 may be provided as a single inorganic layer or at least one thereof may be provided as a plurality of inorganic layers. For example, the first and second inorganic encapsulation layers 151, 153 may be formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, etc.

In the encapsulation structure 150, each of the first and second inorganic encapsulation layers 151, 153 and the organic encapsulation layer 152 may be formed of an insulating material, thus preventing interference during driving of the light emitting device ED and the thin film transistor T1 thereunder.

As shown in FIG. 2, the light emitting display device 1000 according to an aspect of the present disclosure is configured such that a light emitting device ED including an anode 141 and a cathode 143 facing each other and an intermediate layer 142 made of a light emitting material between the anode and the cathode is provided to each sub-pixel SP (FIG. 1).

The intermediate layer 142 may further include an emission layer EL, hole-related layers such as a hole transport layer HTL and a hole injection layer HIL under the emission layer EL, and electron-related layers such as an electron transport layer ETL and an electron injection layer EIL on the emission layer EL. In some cases, the intermediate layer 142 may be formed in a multi-stack structure in which a plurality of emission layers is stacked.

As shown in FIG. 2, the intermediate layer 142 may be provided between banks 145, but the light emitting display device of the present disclosure is not limited thereto. At least one layer in the intermediate layer 142 may be integrally formed over the plurality of sub-pixels SP. For example, at least one layer selected from among the hole-related layers and the electron-related layers may be continuously provided on the banks 145, as well as between the neighboring banks 145.

To control operation of the light emitting device ED for each sub-pixel, the sub-pixel SP further includes a thin film transistor T1 connected to the light emitting device ED.

The thin film transistor T1 includes a semiconductor layer 115, a gate electrode 105 that overlaps a channel region of the semiconductor layer 115, a gate insulating film 110 interposed between the gate electrode 105 and the semiconductor layer 115, and a first electrode 121 and a second electrode 122 connected to respective sides of the semiconductor layer 115.

The semiconductor layer 115 may be formed of at least one selected from among an oxide semiconductor, crystalline silicon, and amorphous silicon.

Also, the semiconductor layer 115 may further include a conductive layer between the first electrode 121 and the semiconductor layer 115 or between the second electrode 122 and the semiconductor layer 115.

An interlayer insulating film 120 may be provided between the semiconductor layer 115 and the first and second electrodes 121, 122 except for portions where the semiconductor layer 115 and the first and second electrodes 121, 122 are directly connected to each other.

Each of the gate insulating film 110 and the interlayer insulating film 120 is provided in the form of an inorganic insulating film. For example, the gate insulating film 110 and the interlayer insulating film 120 may be formed of an oxide film, a nitride film, an oxynitride film, or the like.

Although FIG. 2 shows an example in which the gate electrode 105 is located at a lower position than the semiconductor layer 115, the thin film transistor T1 of the light emitting display device of the present disclosure is not limited thereto. The gate electrode may be located at a higher position than the semiconductor layer, and may be located at the same position as the first and second electrodes 121, 122 as necessary.

Meanwhile, each of the gate electrode 105 and the first and second electrodes 121, 122 may be formed in a single layer or multiple layers of any one or alloys thereof selected from the group consisting of copper (Cu), molybdenum (Mo), aluminum (Al), chromium (Cr), gold (Au), titanium (Ti), nickel (Ni), neodymium (Nd), tantalum (Ta), and tungsten (W). For example, when the gate electrode 105 and the first and second electrodes 121, 122 are provided in a single layer, they may be formed of any one or alloys thereof selected from the group consisting of molybdenum (Mo), aluminum (Al), chromium (Cr), gold (Au), titanium (Ti), nickel (Ni), neodymium (Nd), and copper (Cu). Also, when the gate electrode 105 and the first and second electrodes 121, 122 are formed in multiple layers, a double layer of molybdenum/aluminum-neodymium, molybdenum/aluminum, titanium/aluminum, or copper/molybdenum-titanium may be provided. Alternatively, the gate electrode 105 and the first and second electrodes 121, 122 may be provided in a triple layer of moly bdenum/aluminum-neodymium/molybdenum, molybdenum/aluminum/molybdenum, titanium/aluminum/titanium, or moly bdenum-titanium/copper/molybdenum-titanium. However, the present disclosure is not limited thereto, and the gate electrode 105 and the first and second electrodes 121, 122 may be provided in multiple layers made of any one or alloys thereof selected from the group consisting of molybdenum (Mo), aluminum (Al), chromium (Cr), gold (Au), titanium (Ti), nickel (Ni), neodymium (Nd), and copper (Cu).

One of the first electrode 121 and the second electrode 122 is a source electrode, and the remaining one is a drain electrode. The thin film transistor T1 functions as a driving thin film transistor that drives the light emitting device ED, and the sub-pixel SP may further include a thin film transistor such as a switching thin film transistor and/or a sensing thin film transistor in addition to the illustrated thin film transistor T1.

A passivation film 125 and a planarization film 130 are provided on the thin film transistor T1 to protect the thin film transistor T1.

Also, the light emitting device ED may be provided on the planarization film 130.

The planarization film 130 and the passivation film 125 contain therein a connection hole exposing the second electrode 122, and the anode 141 is connected to the second electrode 122 through the connection hole and is formed on the planarization film 130. The anode 141 of the light emitting device ED and the second electrode 122 of the thin film transistor T1 may be electrically connected to each other through the connection hole provided in the planarization film 130 and the passivation film 125.

The light emitting device ED may have a bank 145 on the planarization film 130 to expose the anode 141 corresponding to the emission portion of each sub-pixel.

The anode 141 of the light emitting device ED is connected to the thin film transistor T1 of each sub-pixel and is formed for each sub-pixel, and the cathode 143 may be provided in common to the plurality of sub-pixels SP.

Although not shown in FIG. 2, a capping layer may be further provided on the cathode 143 to increase light emission efficiency of the light emitting device ED and protect the light emitting device ED. The capping layer may be formed before the encapsulation structure and may be formed during a deposition process for forming the light emitting device ED.

At least one dam pattern 155a, 155b may be configured such that the same material 130a as the planarization film 130 and the same material 145a as the bank 145 are stacked.

Below is a description of a method of manufacturing the light emitting display device according to the first aspect of the present disclosure having the configuration as described above.

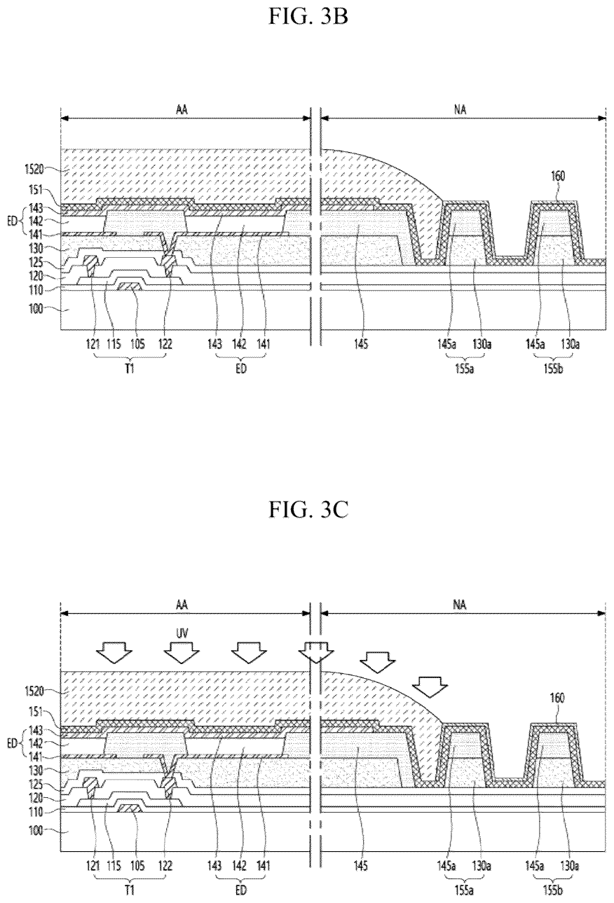

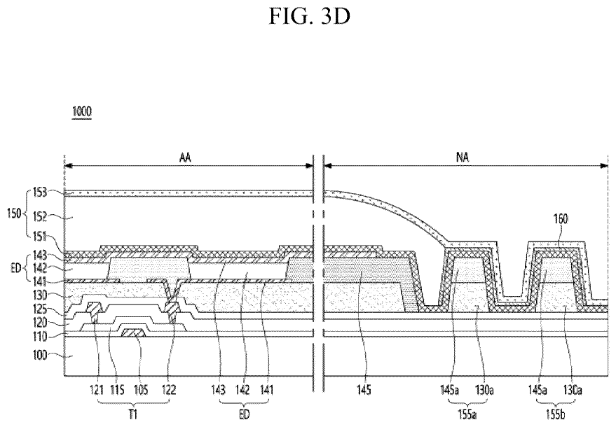

FIGS. 3A to 3D are cross-sectional views showing a process of manufacturing the light emitting display device according to the first aspect of the present disclosure.

As shown in FIG. 3A, a substrate 100 having an active area AA including a plurality of sub-pixels and a non-active area NA surrounding the active area is prepared.

A thin film transistor T1 including a gate electrode 105, a gate insulating film 110, a semiconductor layer 115, a first electrode 121, and a second electrode 122 is formed in each sub-pixel.

A passivation film 125 and a planarization film 130 are sequentially formed on the substrate on which the thin film transistor T1 is formed.

A connection hole through which an upper portion of the second electrode 122 of the thin film transistor T1 is exposed is formed by selectively removing the passivation film 125 and the planarization film 130.

An anode component (a metal layer or a transparent conductive layer) is formed on the entire surface of the planarization film 130 and then selectively removed, thus forming an anode 141 that is connected to the second electrode 122 through the connection hole in the passivation film 125 and the planarization film 130 and classified for each sub-pixel.

A bank 145 is formed to expose the emission portion of the anode 141. The bank 145 may extend from the edge of the active area AA to a part of the non-active area 145.

In the process of forming the bank 145, at least one dam pattern 155a, 155b may be formed in the non-active area NA. At least one dam pattern 155a, 155b may be configured such that the same material 130a as the planarization film 130 and the same material 145a as the bank 145 are stacked.

Specifically, the same material 130a as the planarization film 130 and the same material 145a as the bank 145 are stacked in the non-active area NA, after which at least one dam pattern 155a, 155b may be formed by selectively removing the same material 130a as the planarization film 130 and the same material 145a as the bank 145 when the bank 145 is formed.

Subsequently, an intermediate layer 142 and a cathode 143 are formed.

The anode 141, the intermediate layer 142, and the cathode 143 stacked for each sub-pixel form a light emitting device ED.

After completion of formation of the light emitting device ED, an encapsulation structure protecting the light emitting device ED is formed.

Specifically, a first inorganic encapsulation layer 151 is formed in the active area AA and the non-active area NA.

A hydrophilic material layer 160 is formed on the first inorganic encapsulation layer 151 over at least one dam pattern 155a, 155b.

The hydrophilic material layer 160 may be formed in a manner in which a hydrophilic material is formed on the first inorganic encapsulation layer 151 of the active area AA and the non-active area NA, followed by removal of the remaining portion so that the hydrophilic material is left behind only on the first inorganic encapsulation layer 151 over at least one dam pattern 155a, 155b through a photolithography process.

Alternatively, the hydrophilic material layer 160 may be formed only on the first inorganic encapsulation layer 151 over at least one dam pattern 155a, 155b using an inkjet printing process.

As shown in FIG. 3B, a liquid hydrophobic organic material 1520 is applied to an area inward from the hydrophilic material layer 160 and at least one dam pattern 155a, 155b. As such, the liquid hydrophobic organic material 1520 is prevented from spreading onto at least one dam pattern 155a, 155b due to a difference in wettability between the hydrophilic material layer 160 and the hydrophobic organic material.

As shown in FIG. 3C, an organic encapsulation layer 152 is formed by curing the liquid organic material 1520 through irradiation of the liquid organic material 1520 with UV light.

As shown in FIG. 3D, a second inorganic encapsulation layer 153 is formed on the organic encapsulation layer 152 and the hydrophilic material layer 160.

The second inorganic encapsulation layer 153 may cover the organic encapsulation layer 152 and the hydrophilic material layer 160, and may be formed on the first inorganic encapsulation layer 151 to extend outward from the hydrophilic material layer 160.

Therefore, in the light emitting display device according to the present disclosure and the method of manufacturing the same, the hydrophilic material layer 160 is formed on the first inorganic encapsulation layer 151 over at least one dam pattern 155a. 155b before application of the liquid organic encapsulation material, making it possible to guide the organic encapsulation layer 152 inward from the hydrophilic material layer 160 and at least one dam pattern 155a, 155b.

Moreover, in the light emitting display device according to the present disclosure and the method of manufacturing the same, the non-active area NA may be minimized and the effective area of the light emitting display device may be maximized.

### Second Aspect

For the hydrophilic material layer 160 of the present disclosure, when a nanostructure 170 is provided by forming a hydrophilic recrystallization material layer and then performing recrystallization by heat treatment, the liquid hydrophobic organic material may be more effectively prevented from spreading onto at least one dam pattern 155a, 155b.

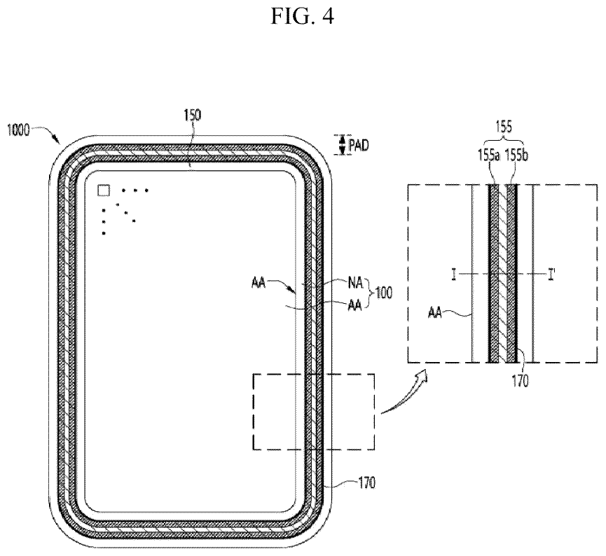

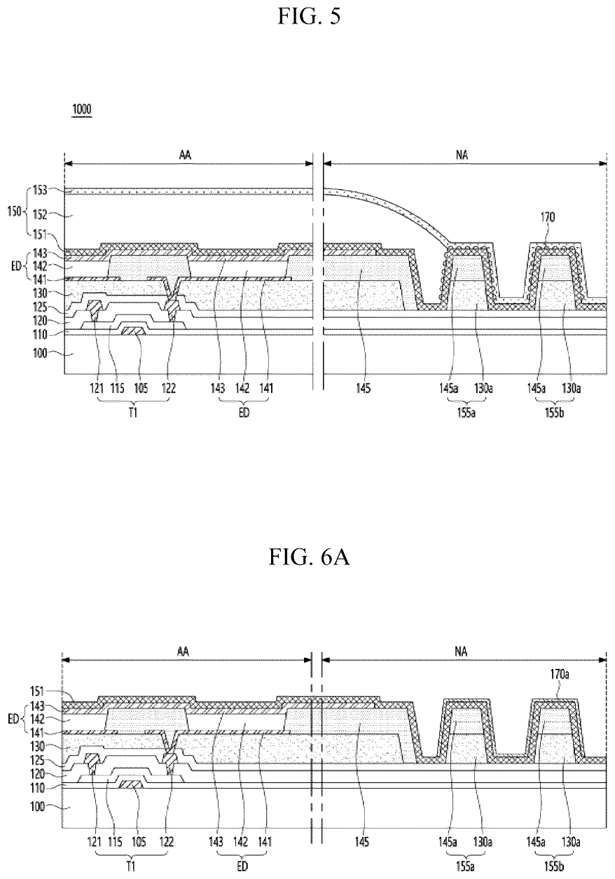

FIG. 4 is a plan view showing a light emitting display device according to a second aspect of the present disclosure. FIG. 5 is a cross-sectional view showing the light emitting display device taken along line I-I′ of FIG. 4 according to the second aspect of the present disclosure.

As shown in FIG. 4, the light emitting display device 1000 according to the second aspect of the present disclosure includes a substrate 100 having an active area AA including a plurality of sub-pixels SP and a non-active area NA surrounding the outer perimeter of the active area AA.

The substrate 100 includes an encapsulation structure 150 (FIG. 5) that protects a light emitting device ED (FIG. 5) provided to each of the sub-pixels SP in at least the active area AA. The encapsulation structure 150 may be provided in the entire active area AA and at least a part of the non-active area NA outside the active area AA.

As shown in FIG. 4, the light emitting display device 1000 according to a second aspect of the present disclosure includes at least one dam pattern 155a, 155b in the non-active area NA of the encapsulation structure 150.

Also, the light emitting display device 1000 according to an aspect of the present disclosure includes a hydrophilic nanostructure 170 over at least one dam pattern 155a, 155b as shown in FIG. 4.

In the encapsulation structure that protects and encapsulates the active area AA, an organic encapsulation layer 152 (FIG. 5) is formed by applying a liquid material, and may have spreadability when applied due to liquid properties. The nanostructure 170 of the present disclosure functions to prevent the hydrophobic organic encapsulation layer 152 made of a liquid material from spreading onto at least one dam pattern 155a, 155b.

A plurality of gate lines and a plurality of data lines crossing each other may be provided in the active area AA of the substrate 100, and sub-pixels SP may be disposed in each area where the plurality of gate lines and the plurality of data lines cross each other. The configuration of the sub-pixels SP may be variously changed depending on the type of light emitting display device.

For example, the sub-pixels SP may be formed in a top emission manner, a bottom emission manner, or a dual emission manner, depending on the configuration thereof. The sub-pixels SP are units capable of emitting light of their own colors with or without a specific type of color filter. For example, the sub-pixels SP may include red, green, and blue sub-pixels. Alternatively, the sub-pixels SP may include, for example, red, blue, white, and green sub-pixels. The sub-pixels SP may have one or more different emission areas depending on light emitting characteristics. For example, sub-pixels emitting blue and other colors may have different emission areas.

One or more sub-pixels SP may constitute one unit pixel. For example, one unit pixel may include red, green, and blue sub-pixels, and the red, green, and blue sub-pixels may be repeatedly arranged. Alternatively, one unit pixel may include red, green, blue, and white sub-pixels, and the red, green, blue, and white sub-pixels may be repeatedly arranged, or the red, green, blue, and white sub-pixels may be arranged in a quad form.

In some embodiments, the sub-pixels SP may include sub-pixels emitting at least two selected from among red light, green light, blue light, yellow light, magenta light, and cyan light. Also, the plurality of sub-pixels SP may emit their own colors with or without a specific type of color filter. However, the present disclosure is not necessarily limited thereto, and the color type, arrangement type, and arrangement order of the sub-pixels SP may vary depending on the light emitting characteristics, device lifespan, and device specifications.

In an aspect according to the present specification, the color type, arrangement type, arrangement order, etc. of the sub-pixels may be configured in various forms depending on the light emitting characteristics, device lifespan, device specifications, and the like, but the present disclosure is not limited thereto.

At least one side of the non-active area NA of the substrate 100 may include a pad portion PAD including a pad electrode. The pad electrode may be connected to the gate lines and the data lines of the active area AA through a link line. The link line may overlap the nanostructure 170) and at least one dam pattern 155a, 155b surrounding the non-active area NA.

The encapsulation structure 150 may not be formed in the pad portion PAD.

However, the present disclosure is not limited thereto, and when the encapsulation structure 150 is multilayered, some layers thereof may be formed in at least a part of the pad portion PAD.

Meanwhile, as shown in FIG. 4, the nanostructure 170) and at least one dam pattern 155a, 155b may be formed in a closed loop shape in the non-active area NA. However, the nanostructure 170 and at least one dam pattern 155a, 155b of the present disclosure are not necessarily a closed loop. In some cases, the nanostructure 170) and at least one dam pattern 155a, 155b may have an opening in at least a part of the substrate 100.

The nanostructure 170 may have the same width in the non-active area NA along each side of the substrate 100. However, the present disclosure is not limited thereto, and the width of the nanostructure 170 may vary depending on the side of the substrate 100. The width of the nanostructure 170 may be increased on any side of the substrate 100 where the liquid material is excessive among sides of the substrate 100. For example, when the substrate 100 has the pad portion PAD at one side thereof as shown in FIG. 4, the non-active area NA corresponding to the side having the pad portion PAD requires a link line for connection between the pad electrode and lines such as the gate lines, the data lines, etc. in the active area AA. In addition, when the light emitting display device includes a gate-in-panel (GIP) circuit having a gate driver configured to drive gate lines by embedding the gate driver in the substrate 100, one side or both sides of the substrate adjacent to the gate lines may include the gate driver through the same process as a process of forming a thin film transistor of the active area AA. In addition, the non-active area NA of the substrate 100 may include a ground line. As described above, the non-active area NA of the substrate 100 may have a density difference on each side due to different lines and circuit types required for the pad portion and the gate driver, and accordingly, a surface step may be generated and thus spreadability of the liquid material may vary. In the light emitting display device of the present disclosure, the width of the nanostructure 170) is set to be different at a side having high step density and a side having low step density, whereby spreading of the organic encapsulation layer may be thoroughly prevented regardless of areas even when the liquid material spreads.

In the active area AA, an image may be displayed by light emitted from each sub-pixel SP.

The pad portion PAD of the non-active area NA may be connected to an external printed circuit film or the like to receive an electrical signal from the outside.

Below is a specific description of a light emitting display device according to an aspect of the present disclosure with reference to a cross-sectional view.

As shown in FIG. 5, the light emitting display device 1000 according to a second aspect of the present disclosure includes a substrate 100 having an active area AA including a plurality of sub-pixels and a non-active area NA surrounding the active area, a light emitting device ED provided to each of the plurality of sub-pixels SP in the active area AA (FIG. 4), and an encapsulation structure 150 covering the light emitting device ED.

The encapsulation structure 150 of the light emitting display device 1000 according to the second aspect of the present disclosure includes at least one dam pattern 155a, 155b provided in the non-active area NA, a first inorganic encapsulation layer 151 provided in the active area AA and the non-active area NA, a hydrophilic nanostructure 170) configured to surround the active area AA in the non-active area NA and provided on the first inorganic encapsulation layer 151 over at least one dam pattern 155a, 155b, a hydrophobic organic encapsulation layer 152 provided on the first inorganic encapsulation layer 151 in an area inward from the nanostructure 170 and at least one dam pattern 155a, 155b, and a second inorganic encapsulation layer 153 configured to cover the hydrophobic organic encapsulation layer 152 and the nanostructure 170 and provided to extend outward from the nanostructure 170.

The first inorganic encapsulation layer 151 and the second inorganic encapsulation layer 153 of the encapsulation structure 150 functionally prevent penetration of water or outside air introduced in a direction perpendicular thereto, and are formed thinly at a thickness of about 1 μm to 2 μm. The first and second inorganic encapsulation layers 151, 153 may be formed in a gaseous state by vacuum deposition. Moreover, the first and second inorganic encapsulation layers 151, 153 are formed throughout the entire substrate 100 except for the pad portion PAD.

The organic encapsulation layer 152 is formed to a high thickness sufficient to cover particles, etc. generated during processes. Since the organic encapsulation layer 152 may be more vulnerable to outside air and water than the first and second inorganic encapsulation layers 151, 153 due to material properties, it may be positioned inward relative to the first and second inorganic encapsulation layers 151, 153.

Since the hydrophobic organic encapsulation layer 152 needs to be formed thick enough to cover particles and large enough to cover at least the active area AA, it may be formed through spin coating using a liquid hydrophobic organic material. However, the liquid hydrophobic organic material may spread beyond a preset design area after coating (application).

In the light emitting display device of the present disclosure, the hydrophilic nanostructure 170 is formed on the first inorganic encapsulation layer 151 over at least one dam pattern 155a, 155b, and thus the liquid hydrophobic organic material is prevented from spreading onto at least one dam pattern 155a, 155b due to an increase in surface roughness between the hydrophilic nanostructure 170 and the hydrophobic organic material.

As a structure that prevents overflow of a liquid material encapsulation layer known to date, at least one dam pattern is provided in the form of a planarization film that protects a thin film transistor array or a bank that defines the emission portion of each sub-pixel. However, such a dam pattern structure has difficulty completely preventing overflow of the liquid material encapsulation layer, and accordingly, a plurality of dams is spaced apart from each other horizontally. Here, the area occupied by the plurality of dam structures and the space between the dams cannot be used for display, which causes an increase in the non-active area. In addition, a multilayered dam may be formed by increasing the width of the planarization film dam pattern at the lower position to align the planarization film and the bank formed in different layers, increasing the area occupied by the dam pattern, which is undesirable.

In the light emitting display device 1000 of the present disclosure, the hydrophilic nanostructure 170 may be formed on the first inorganic encapsulation layer 151 over at least one dam pattern 155a, 155b, so that the liquid hydrophobic organic material may be prevented from spreading onto at least one dam pattern 155a, 155b, thereby solving problems with the structure having the dam pattern such as the area occupied by the dam pattern and expansion of the non-active area.

The hydrophilic nanostructure 170 of the present disclosure may be formed in the light emitting display device through the following process.

A hydrophilic recrystallization material is formed on the first inorganic encapsulation layer 151 over at least one dam pattern 155a, 155b. Then, the recrystallization material is subjected to heat treatment to induce recrystallization of the recrystallization material. Accordingly, a hydrophilic nanostructure 170 having a boundary/crack aspect may be formed.

When the nanostructure 170 is formed by recrystallizing the recrystallization material, the liquid hydrophobic organic material may be further effectively prevented from spreading onto at least one dam pattern 155a, 155b due to an increase in surface roughness between materials having different wettabilities, compared to the first aspect of the present disclosure.

The recrystallization material may include a material having an —OH, —COOH or —POOH ligand and having a glass transition temperature (Tg) of 120° C. or less.

At least one dam pattern 155a, 155b may be configured such that the same material 130a as a planarization film 130 and the same material 145a as a bank 145 are stacked. However, the present disclosure is not limited thereto, and at least one dam pattern may be formed of a material for either the planarization film 130 or the bank 145, or may be formed of a material different from that for the planarization film 130 or the bank 145.

The organic encapsulation layer 152 may be formed of, for example, acrylic resin, methacrylic resin, polyisoprene, vinyl resin, epoxy resin, urethane resin, cellulose resin, or perylene resin.

Each of the first and second inorganic encapsulation layers 151, 153 may be provided as a single inorganic layer or at least one thereof may be provided as a plurality of inorganic layers. For example, the first and second inorganic encapsulation layers 151, 153 may be formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, etc.

In the encapsulation structure 150, each of the first and second inorganic encapsulation layers 151, 153 and the organic encapsulation layer 152 may be formed of an insulating material, thus preventing interference during driving of the light emitting device ED and the thin film transistor T1 thereunder.

As shown in FIG. 5, the light emitting display device 1000 according to the second aspect of the present disclosure is configured such that a light emitting device ED including an anode 141 and a cathode 143 facing each other and an intermediate layer 142 made of a light emitting material between the anode and the cathode is provided to each sub-pixel SP (FIG. 1).

The intermediate layer 142 may further include an emission layer EL, hole-related layers such as a hole transport layer HTL and a hole injection layer HIL under the emission layer EL, and electron-related layers such as an electron transport layer ETL and an electron injection layer EIL on the emission layer EL. In some cases, the intermediate layer 142 may be formed in a multi-stack structure in which a plurality of emission layers is stacked.

As shown in FIG. 5, the intermediate layer 142 may be provided between banks 145, but the light emitting display device of the present disclosure is not limited thereto. At least one layer in the intermediate layer 142 may be integrally formed over the plurality of sub-pixels SP. For example, at least one layer selected from among the hole-related layers and the electron-related layers may be continuously provided on the banks 145, as well as between the neighboring banks 145.

To control operation of the light emitting device ED for each sub-pixel, the sub-pixel SP further includes a thin film transistor T1 connected to the light emitting device ED.

The thin film transistor T1 includes a semiconductor layer 115, a gate electrode 105 that overlaps a channel region of the semiconductor layer 115, a gate insulating film 110 interposed the semiconductor layer 115 and the gate electrode 105, and a first electrode 121 and a second electrode 122 connected to respective sides of the semiconductor layer 115.

The semiconductor layer 115 may be formed of at least one selected from among an oxide semiconductor, crystalline silicon, and amorphous silicon.

Also, the semiconductor layer 115 may further include a conductive layer between the first electrode 121 and the semiconductor layer 115 or between the second electrode 122 and the semiconductor layer 115.

An interlayer insulating film 120 may be provided between the semiconductor layer 115 and the first and second electrodes 121, 122 except for portions where the semiconductor layer 115 and the first and second electrodes 121, 122 are directly connected to each other.

Each of the gate insulating film 110 and the interlayer insulating film 120 is provided in the form of an inorganic insulating film. For example, the gate insulating film 110 and the interlayer insulating film 120 may be formed of an oxide film, a nitride film, an oxynitride film, or the like.

Although FIG. 5 shows an example in which the gate electrode 105 is located at a lower position than the semiconductor layer 115, the thin film transistor T1 of the light emitting display device of the present disclosure is not limited thereto. The gate electrode may be located at a higher position than the semiconductor layer, and may be located at the same position as the first and second electrodes 121, 122 as necessary.

Meanwhile, each of the gate electrode 105 and the first and second electrodes 121, 122 may be formed in a single layer or multiple layers of any one or alloys thereof selected from the group consisting of copper (Cu), molybdenum (Mo), aluminum (Al), chromium (Cr), gold (Au), titanium (Ti), nickel (Ni), neodymium (Nd), tantalum (Ta), and tungsten (W). For example, when the gate electrode 105 and the first and second electrodes 121, 122 are provided in a single layer, they may be formed of any one or alloys thereof selected from the group consisting of molybdenum (Mo), aluminum (Al), chromium (Cr), gold (Au), titanium (Ti), nickel (Ni), neodymium (Nd), and copper (Cu). Also, when the gate electrode 105 and the first and second electrodes 121, 122 are formed in multiple layers, a double layer of molybdenum/aluminum-neodymium, molybdenum/aluminum, titanium/aluminum, or copper/molybdenum-titanium may be provided. Alternatively, the gate electrode 105 and the first and second electrodes 121, 122 may be provided in a triple layer of moly bdenum/aluminum-neodymium/molybdenum, moly bdenum/aluminum/molybdenum, titanium/aluminum/titanium, or moly bdenum-titanium/copper/molybdenum-titanium. However, the present disclosure is not limited thereto, and the gate electrode 105 and the first and second electrodes 121, 122 may be provided in multiple layers made of any one or alloys thereof selected from the group consisting of molybdenum (Mo), aluminum (Al), chromium (Cr), gold (Au), titanium (Ti), nickel (Ni), neodymium (Nd), and copper (Cu).

One of the first electrode 121 and the second electrode 122 is a source electrode, and the remaining one is a drain electrode. The thin film transistor T1 functions as a driving thin film transistor that drives the light emitting device ED, and the sub-pixel SP may further include a thin film transistor such as a switching thin film transistor and/or a sensing thin film transistor in addition to the illustrated thin film transistor T1.

A passivation film 125 and a planarization film 130 are provided on the thin film transistor T1 to protect the thin film transistor T1.

Also, the light emitting device ED may be provided on the planarization film 130.

The planarization film 130 and the passivation film 125 contain therein a connection hole exposing the second electrode 122, and the anode 141 is connected to the second electrode 122 through the connection hole and is formed on the planarization film 130. The anode 141 of the light emitting device ED and the second electrode 122 of the thin film transistor T1 may be electrically connected to each other through the connection hole provided in the planarization film 130 and the passivation film 125.

The light emitting device ED may have a bank 145 on the planarization film 130 to expose the anode 141 corresponding to the emission portion of each sub-pixel.

The anode 141 of the light emitting device ED is connected to the thin film transistor T1 of each sub-pixel and is formed for each sub-pixel, and the cathode 143 may be provided in common to the plurality of sub-pixels SP.

Although not shown in FIG. 5, a capping layer may be further provided on the cathode 143 to increase light emission efficiency of the light emitting device ED and protect the light emitting device ED. The capping layer may be formed before the encapsulation structure and may be formed during a deposition process for forming the light emitting device ED.

At least one dam pattern 155a, 155b may be configured such that the same material 130a as the planarization film 130 and the same material 145a as the bank 145 are stacked.

Below is a description of a method of manufacturing the light emitting display device according to the second aspect of the present disclosure having the configuration as described above.

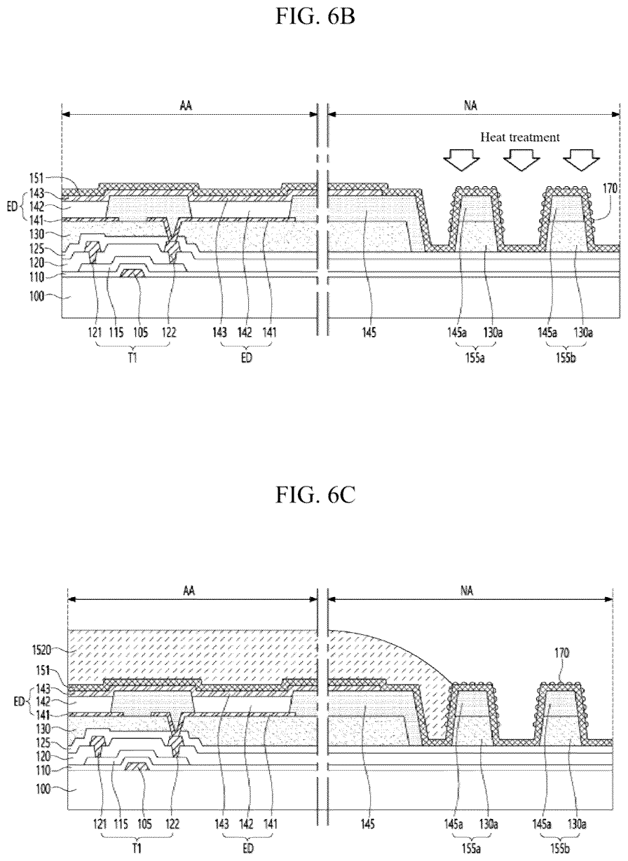

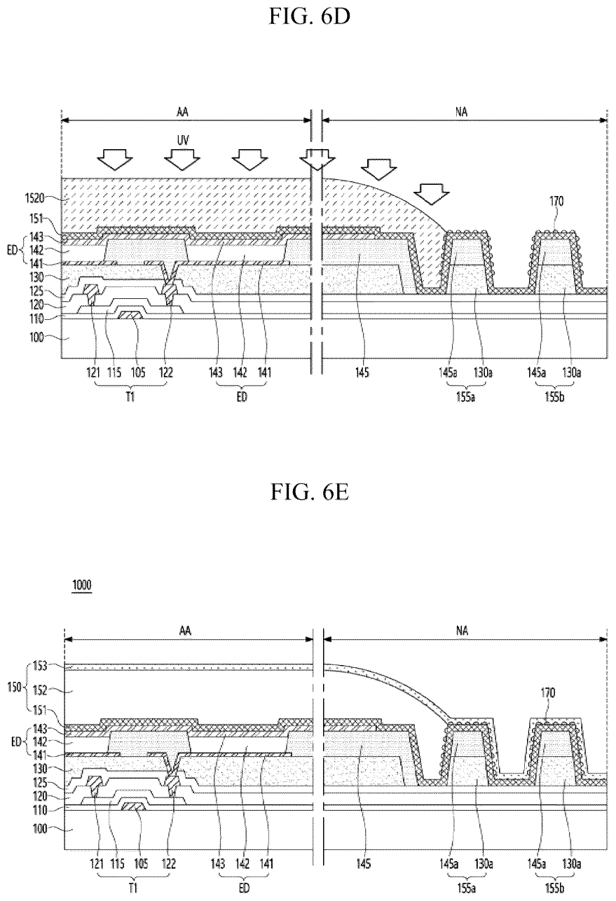

FIGS. 6A to 6E are cross-sectional views showing a process of manufacturing the light emitting display device according to the second aspect of the present disclosure.

As shown in FIG. 6A, a substrate 100 having an active area AA including a plurality of sub-pixels and a non-active area NA surrounding the active area is prepared.

A thin film transistor T1 including a gate electrode 105, a gate insulating film 110, a semiconductor layer 115, a first electrode 121, and a second electrode 122 is formed in each sub-pixel.

A passivation film 125 and a planarization film 130 are sequentially formed on the substrate on which the thin film transistor T1 is formed.

A connection hole through which an upper portion of the second electrode 122 of the thin film transistor T1 is exposed is formed by selectively removing the passivation film 125 and the planarization film 130.

An anode component (a metal layer or a transparent conductive layer) is formed on the entire surface of the planarization film 130 and then selectively removed, thus forming an anode 141 that is connected to the second electrode 122 through the connection hole in the passivation film 125 and the planarization film 130 and classified for each sub-pixel.

A bank 145 is formed to expose the emission portion of the anode 141. The bank 145 may extend from the edge of the active area AA to a part of the non-active area 145.

In the process of forming the bank 145, at least one dam pattern 155a, 155b may be formed in the non-active area NA. At least one dam pattern 155a, 155b may be configured such that the same material 130a as the planarization film 130 and the same material 145a as the bank 145 are stacked.

Specifically, the same material 130a as the planarization film 130 and the same material 145a as the bank 145 are stacked in the non-active area NA, after which at least one dam pattern 155a, 155b may be formed by selectively removing the same material 130a as the planarization film 130 and the same material 145a as the bank 145 when the bank 145 is formed.

Subsequently, an intermediate layer 142 and a cathode 143 are formed.

The anode 141, the intermediate layer 142, and the cathode 143 stacked for each sub-pixel form a light emitting device ED.

After completion of formation of the light emitting device ED, an encapsulation structure protecting the light emitting device ED is formed.

Specifically, a first inorganic encapsulation layer 151 is formed in the active area AA and the non-active area NA.

A hydrophilic recrystallization material layer 170a is formed on the first inorganic encapsulation layer 151 over at least one dam pattern 155a, 155b.

The hydrophilic recrystallization material layer 170a may be formed in a manner in which a hydrophilic recrystallization material layer is formed on the first inorganic encapsulation layer 151 of the active area AA and the non-active area NA, followed by removal of the remaining portion so that the hydrophilic recrystallization material layer is left behind only on the first inorganic encapsulation layer 151 over at least one dam pattern 155a, 155b through a photolithography process.

Alternatively, the hydrophilic recrystallization material layer 170a may be formed only on the first inorganic encapsulation layer 151 over at least one dam pattern 155a, 155b using an inkjet printing process.

The hydrophilic recrystallization material layer 170a may include a material having an —OH ligand, a —COOH ligand, or a —POOH ligand and having a glass transition temperature (Tg) of 120° C. or less.

As shown in FIG. 6B, the hydrophilic recrystallization material layer 170a is subjected to heat treatment to induce recrystallization of the recrystallization material layer. Accordingly, a hydrophilic nanostructure 170 having a boundary/crack aspect may be formed.

As shown in FIG. 6C, a liquid hydrophobic organic material 1520 is applied to an area inward from the hydrophilic nanostructure 170 and at least one dam pattern 155a, 155b. As such, due to an increase in surface roughness between the hydrophilic nanostructure 170 and the hydrophobic organic material, the liquid hydrophobic organic material 1520 may be prevented from spreading onto at least one dam pattern 155a, 155b. When the hydrophilic nanostructure 170 is formed rather than the hydrophilic material layer 160 of the first aspect, the liquid hydrophobic organic material 1520 may be more effectively prevented from spreading onto at least one dam pattern 155a, 155b.

As shown in FIG. 6D, an organic encapsulation layer 152 is formed by curing the liquid organic material 1520 through irradiation of the liquid organic material 1520 with UV light.

As shown in FIG. 6E, a second inorganic encapsulation layer 153 is formed on the organic encapsulation layer 152 and the hydrophilic nanostructure 170.

The second inorganic encapsulation layer 153 may cover the organic encapsulation layer 152 and the hydrophilic nanostructure 170, and may be formed on the first inorganic encapsulation layer 151 to extend outward from the hydrophilic nanostructure 170.

Therefore, in the light emitting display device according to the second aspect of the present disclosure and the method of manufacturing the same, the hydrophilic nanostructure 170 is formed on the first inorganic encapsulation layer 151 over at least one dam pattern 155a, 155b before application of the liquid organic encapsulation material, making it possible to guide the organic encapsulation layer 152 inward from the hydrophilic nanostructure 170 and at least one dam pattern 155a, 155b.

Moreover, in the light emitting display device according to the present disclosure and the method of manufacturing the same, the non-active area NA may be minimized and the effective area of the light emitting display device may be maximized.

In the light emitting display device according to the first or second aspect of the present disclosure and the method of manufacturing the same, the hydrophilic material layer 160 or the hydrophilic recrystallization material layer 170a may include a material having an —OH ligand, a —COOH ligand, or a —POOH ligand and having a glass transition temperature (Tg) of 120° C. or less.

The material having an —OH ligand, a —COOH ligand, or a —POOH ligand and having a glass transition temperature (Tg) of 120° C. or less may include any one selected from among the following:
polyethylene glycol represented by

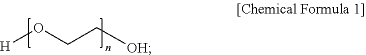

polyvinyl alcohol represented by

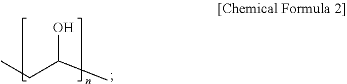

polyethylene glycol represented by

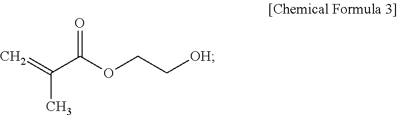

beta-carboxyethyl acrylate represented by

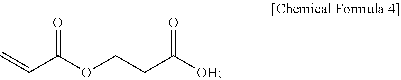

poly-2-hydroxyethyl methacrylate represented by

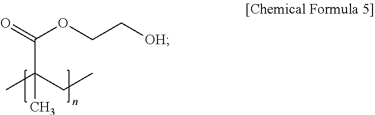

and
N,N-dimethylacrylamide represented by

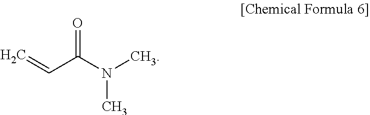

In particular, in the light emitting display device according to the second aspect of the present disclosure and the method of manufacturing the same, the hydrophilic recrystallization material layer 170a is formed of a material having an —OH ligand, a —COOH ligand, or a —POOH ligand and having a glass transition temperature of 120° C. or less, and thus does not affect the characteristics of the light emitting material of the intermediate layer 142, thereby making it possible to induce recrystallization/modification of the recrystallization material layer, ultimately forming a superhydrophilic nanostructure 170 by increasing a domain boundary/crack on the dam pattern through additional heat treatment.

### Third Aspect

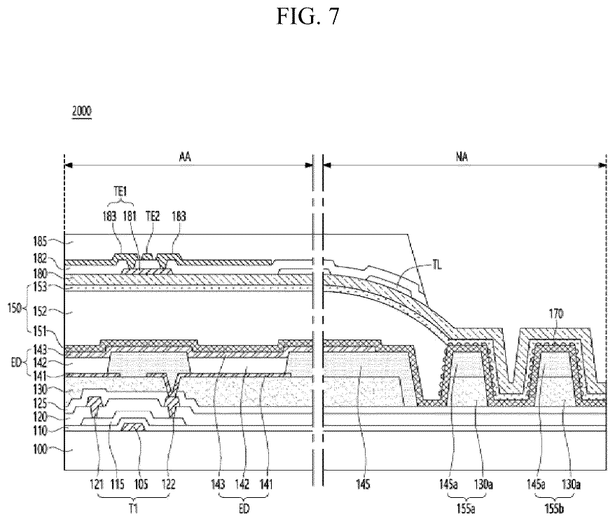

FIG. 7 is a cross-sectional view showing a light emitting display device taken along line I-I′ of FIG. 4 according to a third aspect of the present disclosure.

As shown in FIG. 7, the light emitting display device 2000 according to the third aspect of the present disclosure is different in view of further including first and second touch electrodes TE1, TE2 on an encapsulation structure 150.

In the light emitting display device 2000 in which the first and second touch electrodes TE1, TE2 are provided on the encapsulation structure 150, the touch position may be detected by sensing a change in capacitance in the first touch electrode TE1 and the second touch electrode TE2 depending on the user's touch.

The first and second touch electrodes TE1, TE2 may be configured to cross each other.

The first touch electrode TE1 may include a plurality of first touch electrode patterns 183 spaced apart from each other and a bridge electrode 181 electrically connecting the adjacent first touch electrode patterns 183 to each other. An intermediate touch insulating film 182 may be further provided between the bridge electrode 181 and the first touch electrode patterns 183, except for connection portions between the bridge electrode 181 and the first touch electrode patterns 183.

A touch buffer layer 180 may be further provided between the encapsulation structure 150 and the first and second touch electrodes TE1, TE2, and the bridge electrode 181 may be positioned on the touch buffer layer 180.

The plurality of first touch electrode patterns 183 of the first touch electrode TE1 and the second touch electrode TE2 may be positioned on the same layer. For example, the plurality of first touch electrode patterns 183 of the first touch electrode TE1 and the second touch electrode TE2 may be positioned on the intermediate touch insulating film 182.

A touch link line TL may be further provided to the same layer as the bridge electrode 181, and the touch link line TL may be connected to a touch pad portion (not shown) provided in a part of the non-active area NA of the substrate 100.

The first and second touch electrodes TE1, TE2 may be protected by a touch passivation film 185.

The light emitting display device 2000 according to the third aspect of the present disclosure may include the hydrophilic material layer 160 or the hydrophilic nanostructure 170) in the non-active area NA as described in FIG. 2 or 5. In the configuration including the first and second touch electrodes TE1, TE2 for touch sensing, any one insulating film selected from among the touch buffer film 180, the intermediate touch insulating film 182, and the touch passivation film 185 may overlap the hydrophilic material layer 160 or the hydrophilic nanostructure 170).

In the light emitting display device according to an aspect of the present disclosure and the method of manufacturing the same, the hydrophilic material layer or the hydrophilic nanostructure may be formed on the first inorganic encapsulation layer over at least one dam pattern before application of the liquid organic encapsulation material, so that the liquid organic encapsulation material may be prevented from spreading onto at least one dam pattern during application thereof.

Since the liquid organic encapsulation material may be prevented from spreading onto at least one dam pattern during application thereof by virtue of the hydrophilic material layer or the hydrophilic nanostructure that is formed, introduction of outside air and water into the light emitting display device from the lateral side may be prevented.

In addition, since the liquid organic encapsulation material may be prevented from spreading onto at least one dam pattern during application thereof, the non-active area may be minimized and the effective area of the light emitting display device may be maximized.

The light emitting display device according to an aspect of the present disclosure includes a substrate having an active area including a plurality of sub-pixels and a non-active area surrounding the active area, a light emitting device provided to each of the plurality of sub-pixels, at least one dam pattern provided in the non-active area to surround the active area, a first inorganic encapsulation layer configured to cover the light emitting device and provided in the active area and the non-active area including at least one dam pattern, a hydrophilic material layer configured to surround the active area and provided on the first inorganic encapsulation layer over at least one dam pattern, an organic encapsulation layer provided on the first inorganic encapsulation layer in an area inward from the hydrophilic material layer, and a second inorganic encapsulation layer configured to cover the organic encapsulation layer and the hydrophilic material layer and provided on the first inorganic encapsulation layer to extend outward from the hydrophilic material layer.

The light emitting display device according to another aspect of the present disclosure includes a substrate having an active area including a plurality of sub-pixels and a non-active area surrounding the active area, a light emitting device provided to each of the plurality of sub-pixels, at least one dam pattern provided in the non-active area to surround the active area, a first inorganic encapsulation layer configured to cover the light emitting device and provided in the active area and the non-active area including at least one dam pattern, a nanostructure configured to surround the active area and provided on the first inorganic encapsulation layer over at least one dam pattern, an organic encapsulation layer provided on the first inorganic encapsulation layer in an area inward from the nanostructure, and a second inorganic encapsulation layer configured to cover the organic encapsulation layer and the nanostructure and provided on the first inorganic encapsulation layer to extend outward from the nanostructure.

The nanostructure may be formed of a hydrophilic material.

The nanostructure may be formed of a material having an —OH ligand, a —COOH ligand, or a —POOH ligand and having a glass transition temperature of 120° C. or less.

The nanostructure may be formed of any one material selected from among ethylene glycol, vinyl alcohol, ethylene glycol, beta-carboxyethyl acrylate, 2-hydroxyethyl methacrylate, and N,N-dimethylacrylamide.

The nanostructure may be formed of any one material selected from among materials represented by the following chemical formulas.

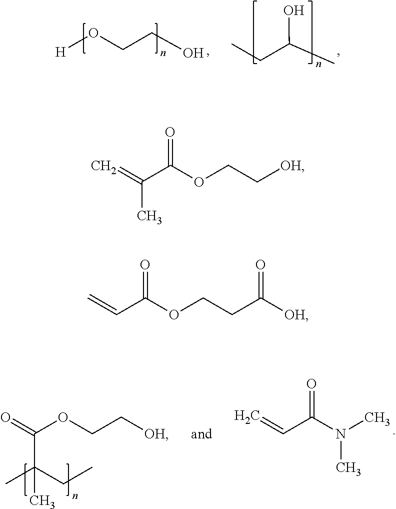

Touch electrodes may be further included on the second inorganic encapsulation layer corresponding to the active area.

In addition, the method of manufacturing the light emitting display device according to an aspect of the present disclosure to achieve the same purpose includes preparing a substrate having an active area including a plurality of sub-pixels and a non-active area surrounding the active area, forming a light emitting device in each of the plurality of sub-pixels, forming at least one dam pattern in the non-active area to surround the active area, forming a first inorganic encapsulation layer covering the light emitting device in the active area and the non-active area including at least one dam pattern, forming a nanostructure surrounding the active area on the first inorganic encapsulation layer over at least one dam pattern, forming an organic encapsulation layer on the first inorganic encapsulation layer in an area inward from the nanostructure, and forming a second inorganic encapsulation layer covering the organic encapsulation layer and the nanostructure on the first inorganic encapsulation layer to extend outward from the nanostructure.

Here, forming the nanostructure may be performed by forming a hydrophilic recrystallization material layer surrounding the active area on the first inorganic encapsulation layer over at least one dam pattern and then performing recrystallization by heat treatment.

The hydrophilic recrystallization material layer may be formed of a material having an —OH ligand, a —COOH ligand, or a —POOH ligand and having a glass transition temperature of 120° C. or less.

The hydrophilic recrystallization material layer may be formed of any one material selected from among ethylene glycol, vinyl alcohol, ethylene glycol, beta-carboxyethyl acrylate, 2-hydroxyethyl methacrylate, and N,N-dimethylacrylamide.

The hydrophilic recrystallization material layer may be formed of any one material selected from among materials represented by the following chemical formulas.

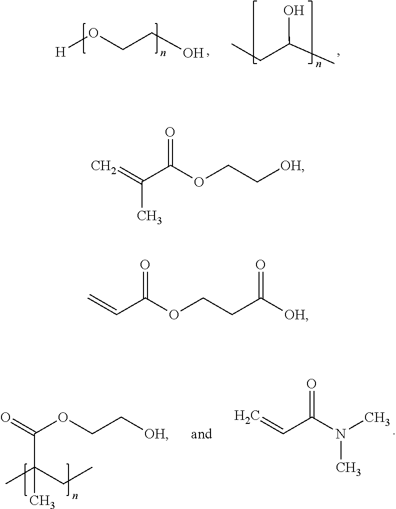

As is apparent from the above description, according to embodiments of the present disclosure, a light emitting display device and a method of manufacturing the same have the following effects.

First, the light emitting display device according to the present disclosure is configured such that a hydrophilic material layer or a nanostructure is formed on a first inorganic encapsulation layer over at least one dam pattern before application of a liquid organic encapsulation material, thereby preventing the liquid organic encapsulation material from spreading onto at least one dam pattern during application thereof.

Second, the liquid organic encapsulation material may be prevented from spreading onto at least one dam pattern during application thereof by virtue of the hydrophilic material layer or the nanostructure that is formed, making it possible to prevent outside air and water from entering the inside of the light emitting display device from the lateral side.

Third, the liquid organic encapsulation material may be prevented from spreading onto at least one dam pattern during application thereof, making it possible to minimize the non-active area and maximize the effective area of the light emitting display device.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A light emitting display device, comprising:
a substrate having an active area comprising a plurality of sub-pixels and a non-active area surrounding the active area;
a light emitting device provided to each of the plurality of sub-pixels;
at least one dam pattern provided in the non-active area to surround the active area;
a first inorganic encapsulation layer configured to cover the light emitting device and provided in the active area and the non-active area comprising the at least one dam pattern;
a hydrophilic material layer configured to surround the active area and provided on the first inorganic encapsulation layer over the at least one dam pattern;
an organic encapsulation layer provided on the first inorganic encapsulation layer in an area inward from the hydrophilic material layer; and
a second inorganic encapsulation layer configured to cover the organic encapsulation layer and the hydrophilic material layer, and provided on the first inorganic encapsulation layer and the hydrophilic material layer to extend outward from the hydrophilic material layer.

2. The light emitting display device according to claim 1, wherein the hydrophilic material layer comprises a material having an —OH ligand, a —COOH ligand, or a —POOH ligand and having a glass transition temperature of 120° C. or less.

3. The light emitting display device according to claim 1, wherein the hydrophilic material layer comprises any one material selected from among ethylene glycol, vinyl alcohol, ethylene glycol, beta-carboxyethyl acrylate, 2-hydroxyethyl methacrylate, and N,N-dimethylacrylamide.

4. The light emitting display device according to claim 1, wherein the hydrophilic material layer comprises any one material selected from among materials represented by chemical formulas below:

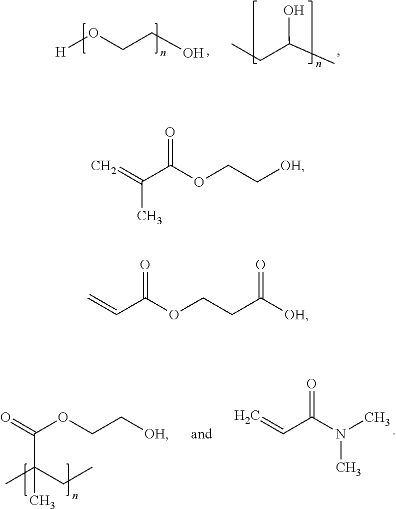

5. A light emitting display device, comprising:
a substrate having an active area comprising a plurality of sub-pixels and a non-active area surrounding the active area;
a light emitting device provided to each of the plurality of sub-pixels;
at least one dam pattern provided in the non-active area to surround the active area;
a first inorganic encapsulation layer configured to cover the light emitting device and provided in the active area and the non-active area comprising the at least one dam pattern;
a nanostructure configured to surround the active area and provided on the first inorganic encapsulation layer over the at least one dam pattern;
an organic encapsulation layer provided on the first inorganic encapsulation layer in an area inward from the nanostructure; and
a second inorganic encapsulation layer configured to cover the organic encapsulation layer and the nanostructure and provided on the first inorganic encapsulation layer and the nanostructure to extend outward from the nanostructure.

6. The light emitting display device according to claim 5, wherein the nanostructure comprises a hydrophilic material.

7. The light emitting display device according to claim 5, wherein the nanostructure comprises a material having an —OH ligand, a —COOH ligand, or a —POOH ligand.

8. The light emitting display device according to claim 5, wherein the nanostructure comprises a material having an —OH ligand, a —COOH ligand, or a —POOH ligand and having a glass transition temperature of 120° C. or less.

9. The light emitting display device according to claim 5, wherein the nanostructure comprises any one material selected from among ethylene glycol, vinyl alcohol, ethylene glycol, beta-carboxyethyl acrylate, 2-hydroxyethyl methacrylate, and N,N-dimethylacrylamide.

10. The light emitting display device according to claim 5, wherein the nanostructure comprises any one material selected from among materials represented by chemical formulas below:

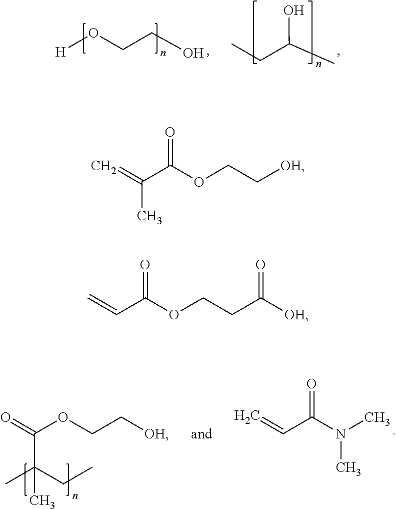

11. The light emitting display device according to claim 5, wherein the at least one dam pattern comprises at least one layer of a planarization film or a bank.

12. The light emitting display device according to claim 5, further comprising touch electrodes on the second inorganic encapsulation layer corresponding to the active area.

13. A method of manufacturing a light emitting display device, comprising:
preparing a substrate having an active area comprising a plurality of sub-pixels and a non-active area surrounding the active area;
forming a light emitting device in each of the plurality of sub-pixels;
forming at least one dam pattern in the non-active area to surround the active area;
forming a first inorganic encapsulation layer covering the light emitting device in the active area and the non-active area comprising the at least one dam pattern;
forming a nanostructure surrounding the active area on the first inorganic encapsulation layer over the at least one dam pattern;
forming an organic encapsulation layer on the first inorganic encapsulation layer in an area inward from the nanostructure; and
forming a second inorganic encapsulation layer covering the organic encapsulation layer and the nanostructure on the first inorganic encapsulation layer and the nanostructure to extend outward from the nanostructure.

14. The method according to claim 13, wherein forming the nanostructure comprises forming a hydrophilic recrystallization material layer surrounding the active area on the first inorganic encapsulation layer over the at least one dam pattern and then performing recrystallization by heat treatment.
